(19) United States
(12) Patent Application Publication
(10) Pub. No.: US 2025/0030009 A1
(43) Pub. Date: Jan. 23, 2025

(54) LAYER SYSTEM, ELECTRODE PLATE COMPRISING SUCH A LAYER SYSTEM, PROCESS FOR PRODUCTION THEREOF, AND FUEL CELL, ELECTROLYZER OR REDOX FLOW CELL

(71) Applicant: Schaeffler Technologies AG & Co. KG, Herzogenaurach (DE)

(72) Inventors: Jeevanthi Vivekananthan, Krefeld (DE); Ladislaus Dobrenizki, Höchstadt (DE); Romina Baechstaedt, Wooster, OH (US); Nathan Kruppe, Nürnberg (DE); Jan Martin Stumpf, Erlangen (DE); Astrid Heckl, Abenberg (DE)

(21) Appl. No.: 18/707,105

(22) PCT Filed: Sep. 30, 2022
(86) PCT No.: PCT/DE2022/100729

§ 371 Date: May 2, 2024

(30) Foreign Application Priority Data
Nov. 2, 2021 (DE) 102021128462.7

(51) Int. Cl. H01M 4/90; H01M 4/86; H01M 4/88

(52) U.S. Cl. CPC H01M 4/9025; H01M 4/8871; H01M 4/8882; H01M 2004/8694

(57) ABSTRACT

The invention relates to a layer system (1) for coating of a substrate (2a) to form an electrode plate (2), comprising at least one coating (1a) of metal oxide, wherein the coating (1a) includes a homogeneous polycrystalline doped indium tin oxide layer, atop which is a polycrystalline doped indium tin oxide layer composed of a network of nanofibers (6), wherein the indium tin oxide is doped with at least one element from the group comprising carbon, nitrogen, boron, fluorine, hydrogen, phosphorus, sulfur, chlorine, bromine, aluminium, silicon, titanium, chromium, cobalt, nickel, copper, zirconium, niobium, molybdenum, silver, antimony, hafnium, tantalum, tungsten. The invention further relates to an electrode plate comprising such a layer system, to a process for production thereof, and to a fuel cell, an electrolyzer or a redox flow cell comprising at least one such electrode plate.

### CROSS-REFERENCE TO RELATED APPLICATIONS

The present application is the U.S. National Phase of PCT Patent Application Number PCT/DE2022/100729, filed on Sep. 30, 2022, which claims priority to German Patent Application Serial Number 10 2021 128 462.7, filed on Nov. 2, 2021, the entire disclosures of which are incorporated by reference herein.

### TECHNICAL FIELD

The disclosure relates to a layer system for coating a substrate to form an electrode plate, comprising at least one coating (1a) made of metal oxide. The disclosure further relates to an electrode plate comprising a substrate and such a layer system and a method for the production thereof. Furthermore, the disclosure relates to a fuel cell, an electrolyzer or a redox flow cell comprising at least one such electrode plate.

### BACKGROUND ART

A bipolar plate for a fuel cell or an electrolyzer is already known from DE 100 58 337 A1, in which a conductive and corrosion-resistant protective coating made of a metal oxide is formed on at least one side of a metal sheet. The metal oxide is formed in particular from an oxide of the elements or alloys from the group comprising tin, zinc and indium. Doping that ensures conductivity and consists of at least one element from the group comprising aluminum, chromium, silver, boron, fluorine, antimony, chlorine, bromine, phosphorus, molybdenum, and carbon can be present in the metal oxide. The metal sheets used are those made of aluminum, copper, stainless steel, chrome-plated stainless steel, titanium, titanium alloys and iron-containing compounds, which can have a coating of at least one of the elements tin, zinc, nickel, and chromium.

### SUMMARY OF THE INVENTION

It is the object of the disclosure to provide an improved layer system for an electrode plate and to provide such a electrode plate. Furthermore, it is the object of the disclosure to provide a method for the production of the electrode plate and to propose a fuel cell, an electrolyzer or a redox flow cell with at least one such electrode plate.

The object is for the layer system for coating a substrate to form an electrode plate, comprising at least one first coating made of metal oxide, wherein the at least one first coating is a homogeneous, polycrystalline doped indium tin oxide layer, and a top layer in the form of a polycrystalline doped indium tin oxide layer made of a network of nanofibers is formed thereon, wherein the indium tin oxide of the at least one first coating and of the top layer is doped with at least one element of the group comprising carbon, nitrogen, boron, fluorine, hydrogen, phosphorus, sulfur, chlorine, bromine, aluminum, silicon, titanium, chromium, cobalt, nickel, copper, zirconium, niobium, molybdenum, silver, antimony, hafnium, tantalum and tungsten.

The layer system is characterized by a high level of long-term stability with simultaneously high electrical conductivity and low cost, since it is extensive or without precious metal. In addition, the layer system ensures excellent corrosion protection for a metallic base material or substrate of an electrode plate, in particular a bipolar plate. An indium tin oxide is also referred to below as ITO (indium tin oxide).

The layer system is preferably formed by a PVD or a CVD process (PVD: physical vapor deposition; CVD: chemical vapor deposition) or a PACVD process (PACVD: plasma-assisted chemical vapor deposition).

Nanofibers are elongated or stem-like structures that have a diameter of up to 200 nm and a length of up to 1000 nm. The nanofibers can be tapered.

For the formation of a top layer made of a network of nanofibers, reference is made here to the publication “3D ITO-nanowire networks as transparent electrode for all terrain substrate”, Qiang Li et al., Scientific Reports (2019) 9:4983. Seeat: https://doi.org/10.1038/s41598-019-41579-2

The applicant could also produce ITO nanofibers for fuel cell, electrolysis and redox flow bipolar plates using non-reactive sputtering technology with a deposition rate of 40 Å/min and from a target made of In₂O₃:SnO₂ with a concentration of 90:10 at %. The temperature and the SnO₂ content are the main growth factors in the production of the ITO nanofibers. Growth occurs by atoms that are vaporized from the target and deposited on a substrate. The temperature range for the growth is 150° C. to 500° C. Increasing the temperature increases the mean fiber length and the mean diameter of the fibers, reduces the adjacent distance and increases the number of fibers per unit area. The SnO₂ content is preferably a maximum of 30 at %. The development of the mean length and the mean diameter of the nanofibers depends on the deposition time. The ITO nanofibers preferably grow on a thin, dense ITO layer.

The preferred overall layer thickness of the layer system is <1 μm and is in particular in the range from 0.01 to 0.5 μm.

A concentration of the elements of the doping in the indium tin oxide is in particular in the range from <0 to 20 at %.

Particularly preferably, first coatings and top layers here are made of indium tin oxide which have an indium content in the range from 70 to 90 at %. Particularly preferably, indium contents are in the range from 75 to 85 at %, which have a high level of electrical conductivity.

In particular, the following layer systems for coating a metallic substrate, preferably made of steel, in particular austenitic steel or austenitic stainless steel, have proven to be advantageous for forming an electrode plate:

### Example 1

| | |
|---|---|
| First coating: | ITO Layer thickness: 100 nm |
| | Doping: 10 at % nitrogen |
| Top layer: | Indium tin oxide nanofibers with 80 |
| | vol % indium content |
| | Layer thickness: 100 nm |
| | Doping: 3-5 at % copper |

### Example 2

| | |
|---|---|
| First coating: | ITO Layer thickness: 100 nm |
| | Doping: 5 at % titanium |
| Further 1st coating: ITO | Layer thickness: 200 nm |
| | Doping: 5 at % nitrogen |
| Top layer: | Indium tin oxide nanofibers with 90 |
| | vol % indium content |
| | Layer thickness: 100 nm |
| | Doping: 3-5 at % carbon |

The object is achieved for an electrode plate comprising a metallic substrate and a layer system according to the disclosure with a structure of the electrode plate in the order: substrate, at least one first coating made of metal oxide and a top layer made of nanofibers.

The substrate preferably has a thickness in the range of 0.001 to 5 mm.

In particular, the substrate is formed from an iron alloy, in particular steel, or titanium or a titanium alloy or aluminum or an aluminum alloy or zinc or a zinc alloy or a tin alloy or copper or a copper alloy or nickel or a nickel alloy or silver or a silver alloy or chromium or a chromium alloy or based on graphite.

This is preferably an electrode plate with a metallic substrate or a metallic carrier plate. A carrier plate can be designed in one or more parts. In particular, the electrode plate is designed as a bipolar plate.

According to the disclosure, the method for producing an electrode plate according to the disclosure comprises the following steps: providing the substrate; forming the underlayer on a surface of the metallic substrate; forming the at least one first coating on the substrate, forming the top layer on the at least one first coating, wherein the at least one first coating and the top layer of metal oxide are formed on the substrate using non-reactive sputtering with an amorphous structure; and annealing the at least one first coating and the top layer at one temperature in the range of 220 to 400° C. in such a way that the amorphous structure is converted into a polycrystalline structure.

This is a deposition process that can be carried out cost-effectively on a series scale and can also be used to produce nanofibers.

The object is further achieved for a fuel cell, in particular an oxygen-hydrogen fuel cell, or an electrolyzer, in particular for producing hydrogen and oxygen from water, or a redox flow cell, in particular comprising at least one organic electrolyte, comprising at least one electrode plate according to the disclosure. The fuel cell preferably comprises at least one polymer electrolyte membrane.

In the test, the layer system showed stability up to at least 1.4 V in relation to Ag/AgCl ex situ under harsh fuel cell conditions in a 0.5-mM H₂SO₄ electrolyte at pH 3+0.1 ppm HF, and is therefore comparable to the precious metal coating. The contact resistance before and after this electrochemical load (see parameters above) is <3 mOhm·cm² at a contact pressure of 100 N/cm² and a measuring temperature of 24° C.

The corrosion currents are <10⁻⁷ A/cm² under the relevant fuel cell application potentials up to 1.0 V in relation to Ag/AgCl.

No attack on the layer or substrate was detected optically or microscopically up to at least 1.4 V in relation to Ag/AgCl. A stainless steel substrate with the material number 1.4404 according to DIN was used as the substrate.

In the test, the layer system showed stability up to at least 2.2 V in relation to the NHE (normal hydrogen electrode) ex situ under harsh electrolysis conditions in an H₂SO₄ electrolyte at pH 4. The contact resistance before and after this electrochemical load (see parameters above) is <3 mOhm·cm² at a contact pressure of 100 N/cm² and a measuring temperature of 24° C.

No attack on the layer or substrate was detected optically or microscopically up to at least 2.2 V in relation to the NHE. A stainless steel substrate with the material number 1.4404 according to DIN was used as the substrate.

### BRIEF DESCRIPTION OF THE DRAWINGS

FIGS. 1 to 4 are intended to explain, by way of example, a layer system according to the disclosure, an electrode plate formed therewith in the form of a bipolar plate and a fuel cell. In the drawings:

FIG. 1 shows a bipolar plate comprising the layer system;

FIG. 2 schematically shows a fuel cell system comprising a plurality of fuel cells;

FIG. 3 shows a cross section through an electrode plate 2 with a layer system shown as an example in an enlarged view; and

FIG. 4 shows a scanning electron micrograph of a top layer.

### DETAILED DESCRIPTION OF EMBODIMENTS

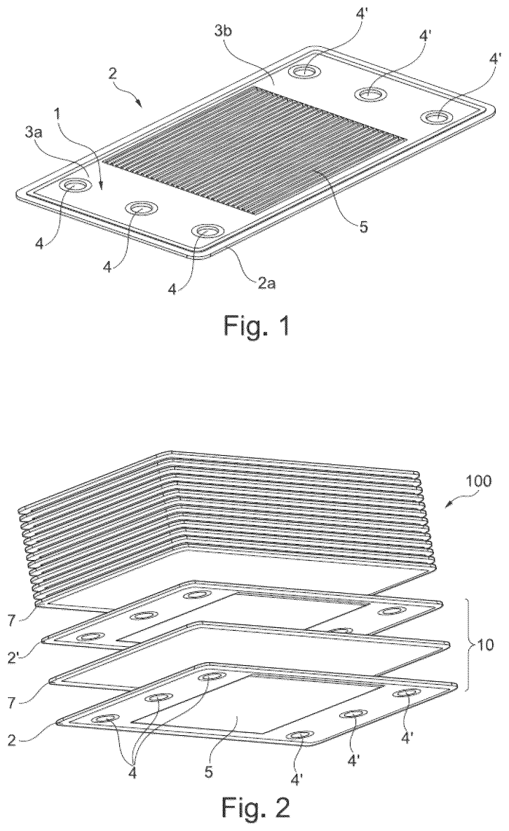

FIG. 1 shows an electrode plate 2 in the form of a bipolar plate having a layer system 1, which here has a metallic substrate 2a or a metal carrier plate made of austenitic stainless steel. The bipolar plate has an inflow region 3a with openings 4 and an outlet region 3b with further openings 4′, which are used to supply a fuel cell with process gases and to remove reaction products from the fuel cell. The bipolar plate also has a gas distribution structure 5 on each side, which is provided for contact with a polymer electrolyte membrane 7 (cf. FIG. 2).

FIG. 2 schematically shows a fuel cell system 100 comprising a plurality of fuel cells 10. Each fuel cell 10 comprises a polymer electrolyte membrane 7 which is adjacent to both sides of the electrode plates 2, 2′ in the form of bipolar plates. The same reference signs as in FIG. 1 indicate identical elements.

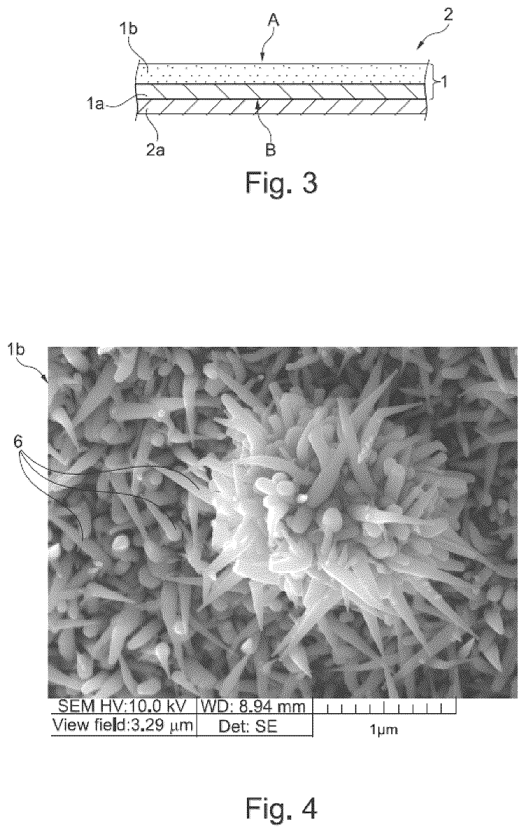

FIG. 3 shows a cross section through an electrode plate 2 according to FIG. 1. It can be seen that there are a substrate 2a, a first coating 1a and a top layer 1b. The first coating 1a is disposed on a side B of the layer system 1 which is arranged facing the substrate 2a. The top layer 1b is disposed on a side A of the layer system 1 which is arranged facing away from the substrate 2a of the electrode plate 2. Alternatively, the layer system 1 can also have a plurality of first coatings 1a.

FIG. 4 shows a scanning electron micrograph of the surface of a top layer 1b made of a network of nanofibers 6, here made of indium tin oxide.

### LIST OF REFERENCE SIGNS

1 Layer system
1a First coating(s)
1b Top layer
2, 2′ Electrode plate
2a Substrate
3a Inflow region
3b Outlet region
4, 4′ Opening
5 Gas distribution structure
6 Nanofibers
7 Polymer electrolyte membrane
10 Fuel cell
100 Fuel cell system
A Side of the layer system 1 facing away from the substrate 2a
B Side of the layer system 1 facing the substrate 2a

1. A layer system for coating a substrate to form an electrode plate, comprising at least one first coating made of metal oxide, wherein the at least one first coating is a homogeneous, polycrystalline doped indium tin oxide layer and a top layer is formed thereon in the form of a polycrystalline doped indium tin oxide layer made of a network of nanofibers, wherein the indium tin oxide of the at least one first coating and the top layer is doped with at least one element of the group comprising carbon, nitrogen, boron, fluorine, hydrogen, phosphorus, sulfur, chlorine, bromine, aluminum, silicon, titanium, chromium, cobalt, nickel, copper, zirconium, niobium, molybdenum, silver, antimony, hafnium, tantalum and tungsten.

2. The layer system according to claim 1, wherein a layer thickness of the layer system is less than 1 μm.

3. The layer system according to claim 1, wherein a concentration of the elements of doping in the indium tin oxide is in the range of >0 to 20 at %.

4. The layer system according to claim 1, wherein the indium tin oxide has an indium content in the range of 70 to 90 at %.

5. An electrode plate comprising a substrate and a layer system according to claim 1, the electrode plate comprising:
at least one first coating made of metal oxide, and
a top layer made of nanofibers.

6. The electrode plate according to claim 5, wherein the substrate has a thickness in the range of 0.001 to 5 mm.

7. The electrode plate according to claim 5, wherein the substrate is formed from at least one an iron alloy, titanium, a titanium alloy, aluminum, an aluminum alloy, zinc, a zinc alloy, a tin alloy, copper, a copper alloy, nickel, a nickel alloy, silver or a silver alloy, chromium, a chromium alloy, or graphite.

8. The electrode plate according to claim 5, wherein the substrate is a metallic substrate.

9. A fuel cell comprising at least one of an oxygen-hydrogen fuel cell, an electrolyzer, or a redox flow cell, comprising at least one electrode plate according to claim 5.

10. The fuel cell according to claim 9, comprising at least one polymer electrolyte membrane.

11. A method for producing an electrode plate according to claim 5, having the following steps:
providing the substrate;
forming the at least one first coating on the substrate, forming the top layer on the at least one first coating, wherein the at least one first coating and the top layer made of metal oxide are formed on the substrate with an amorphous structure by means of non-reactive sputtering; and
annealing the at least one first coating and the top layer at a temperature in the range of 220 to 400° C. in such a way that the amorphous structure is converted into a polycrystalline structure.

12. A bipolar electrode plate comprising:
a substrate;
a layer system, wherein the layer system comprises
at least one first coating comprising a metal oxide, and
a top layer comprising nanofibers.

13. The electrode plate according to claim 12, wherein the at least one first coating comprises a homogeneous, polycrystalline doped indium tin oxide layer.

14. The electrode plate according to claim 13, wherein the top layer is formed on the at least one first coating and comprises a polycrystalline doped indium tin oxide layer formed of a network of nanofibers.

15. The electrode plate according to claim 14, wherein the indium tin oxide of at least one of the at least one first coating or the top layer is doped with at least one element of the group comprising carbon, nitrogen, boron, fluorine, hydrogen, phosphorus, sulfur, chlorine, bromine, aluminum, silicon, titanium, chromium, cobalt, nickel, copper, zirconium, niobium, molybdenum, silver, antimony, hafnium, tantalum and tungsten.

16. The electrode plate according to claim 15, wherein a concentration of the elements of doping in the indium tin oxide is in the range of >0 to 20 at %.

17. The electrode plate according to claim 15, wherein the indium tin oxide has an indium content in the range of 70 to 90 at %.

18. The electrode plate according to claim 12, wherein the substrate is formed from at least one an iron alloy, titanium, a titanium alloy, aluminum, an aluminum alloy, zinc, a zinc alloy, a tin alloy, copper, a copper alloy, nickel, a nickel alloy, silver or a silver alloy, chromium, a chromium alloy, or graphite.

19. The electrode plate according to claim 12, wherein the substrate has a thickness in the range of 0.001 to 5 mm.

20. The electrode plate according to claim 12, wherein the electrode plate is integrated within a fuel cell, wherein the fuel cell comprises at least one of an oxygen-hydrogen fuel cell, an electrolyzer, or a redox flow cell.
